(19) United States
(12) Patent Application Publication
(10) Pub. No.: US 2014/0233196 A1
(43) Pub. Date: Aug. 21, 2014

(54) SWITCH DEVICE

(71) Applicants: Koji Mori, Aichi (JP); Yuichi Fujii, Aichi (JP)

(72) Inventors: Koji Mori, Aichi (JP); Yuichi Fujii, Aichi (JP)

(73) Assignee: OMRON AUTOMOTIVE ELECTRONICS CO., LTD., Aichi (JP)

(21) Appl. No.: 14/181,051

(22) Filed: Feb. 14, 2014

(30) Foreign Application Priority Data
Feb. 15, 2013 (JP) 2013-027271

(51) Int. Cl. H05K 5/00; B60R 16/02

(52) U.S. Cl. CPC H05K 5/0026; B60R 16/02
USPC 361/752; 361/679.01

(57) ABSTRACT

A switch device has an upper case, an operation part attached to the upper case, a lower case fitted in the upper case, a connector provided on a rear side of the lower case, the connector including a connector box and a connector terminal accommodated in the connector box, the connector box including an opening opened in a direction parallel to a lower surface of the lower case, a first wall portion that extends in a width direction of the connector box while being adjacent to a side surface on a side opposite to the opening of the connector box, and a second wall portion that extends in the same direction as the first wall portion while being opposed to the first wall portion with a gap interposed therebetween.

### BACKGROUND OF THE INVENTION

1. Technical Field

The present invention relates to a switch device provided with a connector, particularly to a structure that prevents water from invading through an opening of the connector.

2. Related Art

An automobile includes an automatic window switch in order to perform opening and closing control of a window. Generally the automatic window switch includes an operation knob that is manually operated, a case that swingably supports the operation knob, and a circuit board that is accommodated in the case. The case includes an upper case and a lower case. An operation part is provided on an upper side of the upper case, and a lower side of the upper case is opened. The lower case is fitted in the upper case so as to close the lower side of the upper case. A contact part that switches in response to the operation of the operation knob and an electronic component constituting an electric circuit are provided on the circuit board.

In the automatic window switch, sometimes rainwater invading through an opened window or spilled beverages (hereinafter collectively referred to as “water”) invade into the case. The water invading into the case adheres to the circuit board to generate a shortcircuit of the electric circuit or corrosion of the contact part, which causes a malfunction of the switch.

Some of the automatic window switches include a connector to which a cable is mounted in order to connect the switch to an external control device. The connector includes a connector terminal that is mounted on the circuit board and a connector box in which the connector terminal is accommodated. The connector box is exposed to an outside of the case. Therefore, when the water invades from the opening of the connector box, the short circuit is generated between the connector terminals by the water, or the short circuit or corrosion is generated in the circuit board by the water invading into the case through the connector.

Japanese Unexamined Patent Publication Nos. 9-204842, 2008-130359, and 2012-228903 disclose structures that prevent the water from invading through the connector.

A visor portion that covers an upper portion of the connector included in a side portion of the case, an upper water guard wall that is vertically provided at a front edge of the visor portion, and a side water guard wall that covers both side portion of the connector are provided in an automatic window switch disclosed in Japanese Unexamined Patent Publication No. 9-204842. In the automatic window switch, the water from above the case is received by the visor portion, guided to the side water guard wall by the upper water guard wall, and caused to flow down along the side water guard wall, thereby preventing the water from flowing toward the connector.

Japanese Unexamined Patent Publication No. 2008-130359 discloses an electronic control unit including a visor that covers the upper portion of the connector. In the electronic control unit, a ridge projecting downward is provided along an edge portion of the visor, and a chamfering portion is provided outside the ridge. The ridge prevents a waterdrop dropping on an upper surface of the visor from going round the inside, and the waterdrop drops smoothly down from a lowermost portion of the ridge by the chamfering portion while divided into small waterdrops. Therefore, the water can be prevented from invading into the inside through the connector.

In a vehicle built-in type in-vehicle device disclosed in Japanese Unexamined Patent Publication No. 2012-228903, a connector opening is formed in a rear surface of a chassis including an upper case and a lower case, and a rib projecting upward is provided at a rear end in the upper surface of the upper case. In the in-vehicle device, a width of the rib is larger than that of the connector opening. The in-vehicle device is attached backwardly downward, whereby the water dropping on the upper case and flowing backward upper case is blocked by the rib. Therefore, the water can be prevented from invading into the chassis through the connector opening.

In the devices of Japanese Unexamined Patent Publication Nos. 9-204842, 2008-130359, and 2012-228903, the connector is exposed to the side surface of the case. Therefore, the visor portion or the rib is provided above the connector to prevent water flowing down from invading into the case through the opening of the connector. However, in some of switch devices, the connector is provided on a rear side of the case. In such switch devices, sometimes water flowing down goes round the opening of the connector box along the side surface of the case and the lower surface of the connector box, and invades from the opening into the connector and therefore the case.

For example, it is conceivable as a countermeasure that a wall portion projecting from the lower surface of the case is provided adjacent to the connector box, and that a height of the wall portion is set higher than the connector box. Therefore, the wall portion prevents the water flowing down along the side surface of the case from reaching the connector side, so that the water can be prevented from invading into the connector and the case through the opening of the connector box. However, in this case, since the wall portion projects downward from the connector box, the height of the switch device increases, which becomes the factor to disturb downsizing.

### SUMMARY

According to one or more embodiments of the present invention, a switch device can prevent the invasion of the water into the connector or the case from the opening of the connector box provided on the rear side of the case, and suppress the height to achieve the downsizing.

In accordance with one or more embodiments of the present invention, a switch device includes: an operation part; an upper case to which the operation part is attached; a lower case that is fitted in the upper case; a connector that is provided on a rear side of the lower case, the connector including a connector box and a connector terminal accommodated in the connector box, the connector box including an opening opened in a direction parallel to a lower surface of the lower case; a first wall portion that extends in a width direction of the connector box while being adjacent to a side surface on a side opposite to the opening of the connector box; and a second wall portion that extends in the same direction as the first wall portion while being opposed to the first wall portion with a gap interposed therebetween. In the switch device, a lower surface of the first wall portion and a lower surface of the second wall portion are configured not to project downward from a lower surface of the connector box.

According to the above structure, even if the water flowing down on the side surface of the upper case flows along the lower surface of the connector box, the water flow is blocked between the first wall portion and the second wall portion. Therefore, the water does not go round the opening along the lower surface of the connector box, but the invasion of the water into the connector or the switch device can be prevented. Additionally, the water flow can effectively be blocked even if the first and second wall portions is not set higher than the connector box, so that the height of the switch device can be suppressed to achieve the downsizing.

In the switch device, the lower surface of the first wall portion and the lower surface of the second wall portion may be flush with the lower surface of the connector box.

In the switch device, a projection wall projecting downward may be provided in the lower case so as to cover the side surface except the opening of the connector box, and the first wall portion, the second wall portion, and a groove portion formed between the first wall portion and the second wall portion may be provided in the projection wall.

In the switch device, the connector box may be located at an end of the lower case, and the first wall portion and the second wall portion may be provided near a sidewall of the upper case.

In the switch device, both ends of the groove portion may be opened in the width direction of the connector box.

The switch device may further include a circuit board that is accommodated between the upper case and the lower case. In the switch device, the connector terminal may be connected to the circuit board.

Accordingly, one or more embodiments of the present invention can provide the switch device that prevents the invasion of the water into the connector or the case from the opening of the connector box provided on the rear side of the case and suppresses the height to achieve the downsizing.

### BRIEF DESCRIPTION OF THE DRAWINGS

FIG. 1 is an exploded perspective view illustrating a switch device according to one or more embodiments of the present invention;

FIG. 2 is an assembly drawing of the switch device in FIG. 1;

FIG. 3 is a view of the switch device in FIG. 2 when viewed from a rear side;

FIG. 4 is a perspective view of a lower case;

FIG. 5 is a plan view of the switch device in FIG. 1;

FIG. 6 is a rear view of the switch device in FIG. 1;

FIG. 7 is a side view of the switch device in FIG. 1;

FIG. 8 is a cross-sectional view taken on line A-A in FIG. 5;

FIG. 9 is an enlarged cross-sectional view of B portion in FIG. 8;

FIG. 10 is an enlarged view of C portion in FIG. 3 when viewed from another direction;

FIG. 11 is a cross-sectional view schematically illustrating a main portion of one or more embodiments of the present invention;

FIG. 12 is a cross-sectional view schematically illustrating a main portion of a comparative example;

FIG. 13 is a cross-sectional view schematically illustrating a main portion of another comparative example;

FIG. 14 is a cross-sectional view schematically illustrating a main portion of one or more embodiments of the present invention; and

FIG. 15 is a cross-sectional view schematically illustrating a main portion of one or more embodiments of the present invention.

### DETAILED DESCRIPTION

Hereinafter, embodiments of the present invention will be described with reference to the drawings. In the drawings, similar or equivalent components are designated by identical numerals. The symbol X indicated by an arrow expresses a front-back direction, the symbol Y expresses a horizontal direction, and the symbol Z expresses a vertical direction. The symbol F in the X-direction expresses a frontward direction, the symbol B expresses a backward direction, the symbol L in the Y-direction expresses a leftward direction, the symbol R expresses a rightward direction, the symbol U in the Z-direction expresses an upward direction, and the symbol D expresses a downward direction. In embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

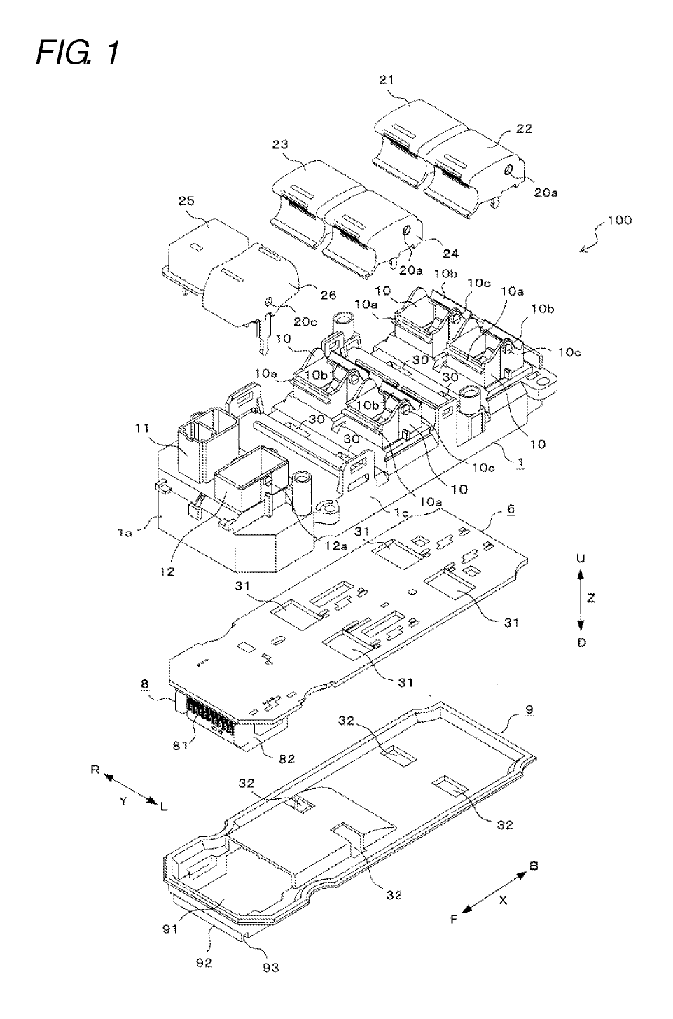

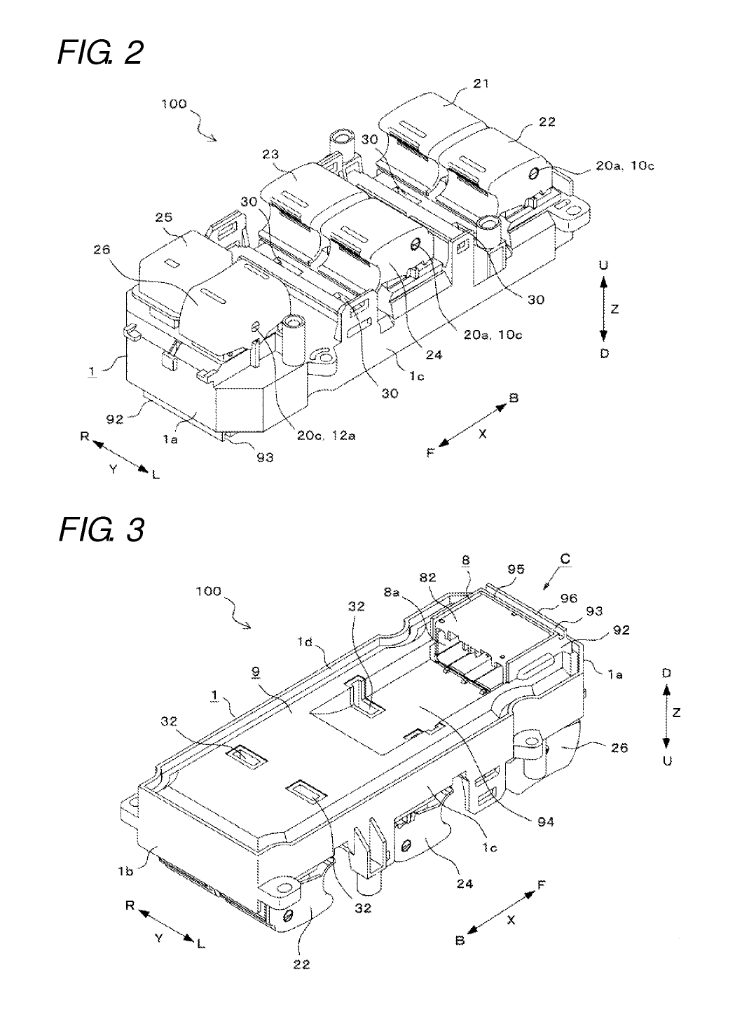

A switch device 100 is a vehicle automatic window switch that is attached to, for example, an armrest (not illustrated) provided inside a door of a driver's seat. As illustrated in FIGS. 1 and 2, the switch device 100 includes plural operation knobs 21 to 26, an upper case 1 to which the operation knobs 21 to 26 are attached, a lower case 9 that is fitted in the upper case 1, and a circuit board 6 that is accommodated in the upper case 1. The operation knobs 21 to 26 are an example of the “operation part” of one or more embodiments of the present invention.

The upper case 1 is formed into a box shape including four sidewalls la to 1d (see FIG. 3). A lower side (D-direction side) of the upper case 1 is opened. The lower case 9 is formed into a flat shape, and fitted in the upper case 1 to close the lower side of the upper case 1. For example, the lower case 9 can be fitted in the upper case 1 by such a well-known method that a protrusion (not illustrated) formed in the lower case 9 is engaged in a notch (not illustrated) formed in the upper case 1.

The operation knobs 21 to 24 are attached to four tubes 10 provided on an upper surface of the upper case 1. Particularly, shaft portions 10c formed in the tubes 10 of the upper case 1 are fitted in holes 20a formed in the operation knobs 21 to 24, whereby the operation knobs 21 to 24 are swingably supported about the shaft portions 10c. For example, the operation knobs 21 to 24 are operated in the case that windows of the driver's seat, a passenger's seat, a left rear seat, and a right rear seat are opened and closed.

The push-type operation knob 25 is supported by a tube 11, which is provided on the upper surface of the upper case 1, while being vertically movable. For example, the operation knob 25 is operated in the case that the windows of the passenger's seat and the rear seats are prohibited to be opened and closed or in the case that the prohibition is lifted.

The seesaw-type operation knob 26 is attached to a tube 12 provided on the upper surface of the upper case 1. Particularly, a shaft portion 12a formed in the tube 12 of the upper case 1 is fitted in a hole 20c formed in the operation knob 26, whereby the operation knob 26 is swingably supported about the shaft portion 12a. For example, the operation knob 26 is operated in the case that the door of each seat is locked or unlocked.

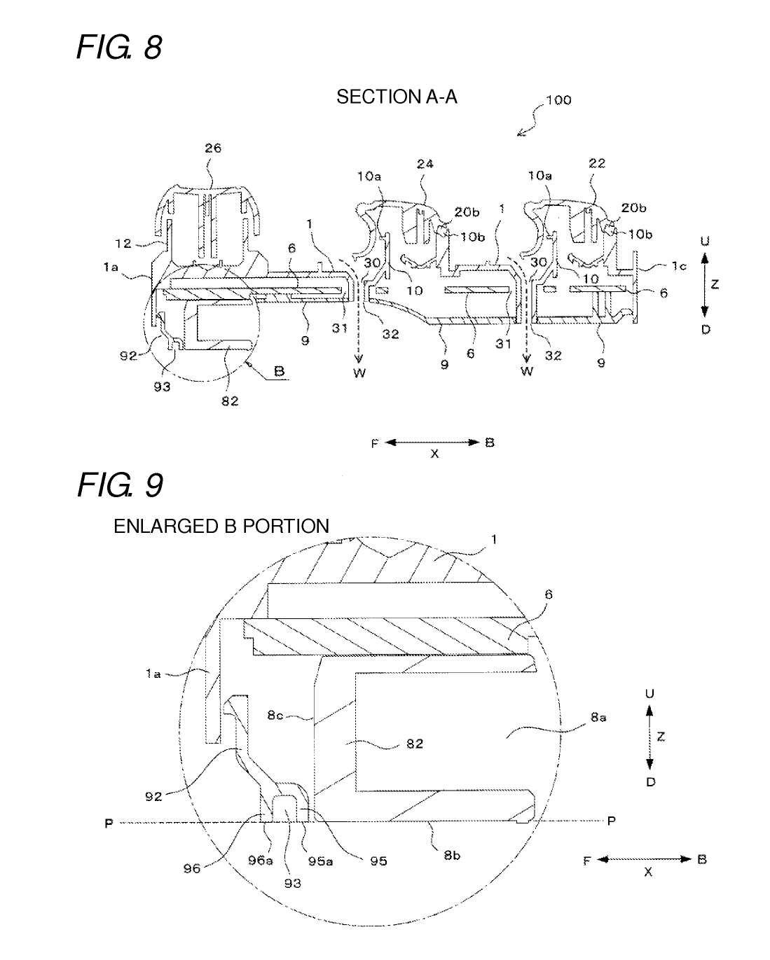

As illustrated in FIG. 1, a rib 10a projecting forward is provided in a sidewall on a frontward side (F-direction side) of each tube 10, and a V-shape groove 10b is provided at an upper end of a sidewall on a backward side (B-direction side). Both ends of the groove 10b are opened. As illustrated in FIG. 8, an inverse V-shape groove 20b corresponding to the groove 10b is provided in a rear portion of each of the operation knobs 21 to 24.

In the upper surface of the upper case 1, drain holes 30 are provided between the back-side tubes 10 supporting the operation knobs 21 and 22 and the front-side tubes 10 supporting the operation knobs 23 and 24. The drain holes 30 are also provided between the front-side tubes 10 supporting the operation knobs 23 and 24 and the tubes 11 and 12 supporting the operation knobs 25 and 26.

A circuit board 6 is constructed by a printed wiring board, and a connector 8 is mounted at an end on a rear side. The connector 8 includes a connector terminal 81 that is connected to the circuit board 6 and a connector box 82 that accommodates the connector terminal 81 therein. As illustrated in FIG. 3, the connector box 82 includes an opening 8a that is opened in the direction (X-direction) parallel to a lower surface of the lower case 9. A terminal (not illustrated) of a cable is inserted in the opening 8a in order to connect the circuit board 6 to an external control device. In addition to the connector 8, a switch contact (not illustrated) that switches in response to the operation of the operation knobs 21 to 26 and an electronic component (not illustrated) constituting an electric circuit are also mounted on the circuit board 6. In the circuit board 6, through-holes 31 are formed at places corresponding to the drain holes 30 of the upper case 1.

As illustrated in FIG. 1, a window 91 is formed in the place corresponding to the connector 8 of the lower case 9. The connector 8 is exposed from the window 91 onto the rear side of the lower case 9. In the lower case 9, drain holes 32 are formed at places corresponding to the drain holes 30 of the upper case 1 and the through-holes 31 of the circuit board 6.

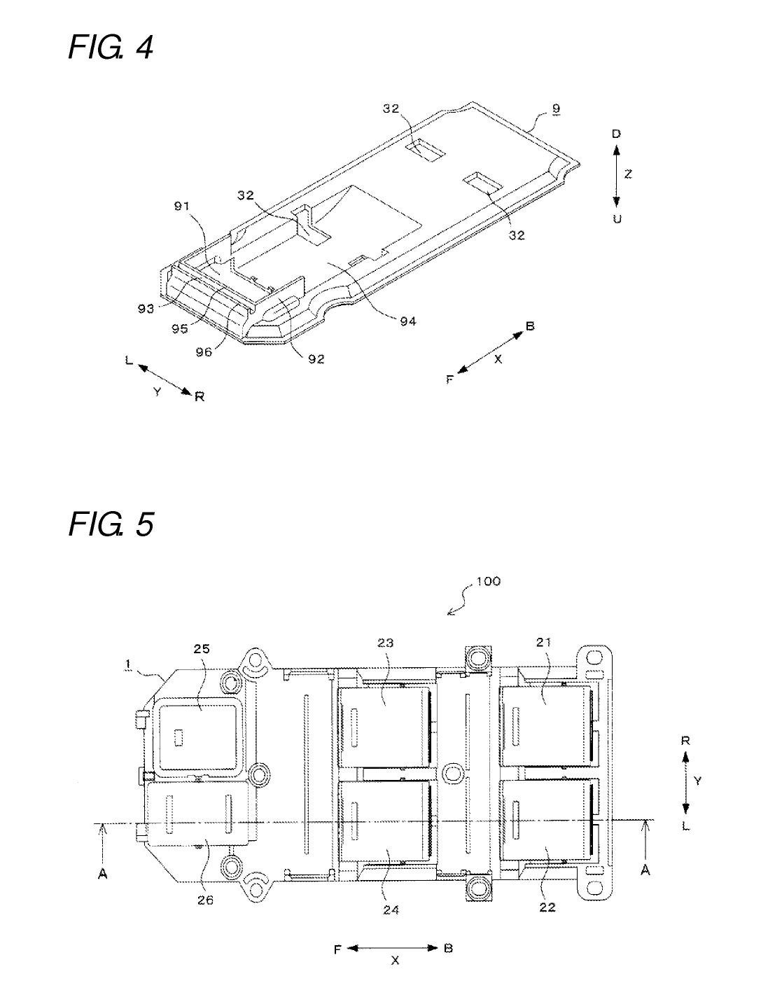

The lower case 9 will be described below in detail with reference to FIGS. 3 and 4. FIG. 3 is a view of the switch device 100 when viewed from the rear side. FIG. 4 is a view of the lower case 9 in FIG. 3 when viewed from another direction. As illustrated in FIG. 3, a projection wall 92 projecting downward (D-direction) is provided on the lower surface of the lower case 9 so as to cover three side surfaces (except opening 8a) of the connector box 82. The projection wall 92 is molded by resin while being integral with the lower case 9. A recess 94 in which a cable (not illustrated) connected to the connector 8 is accommodated is formed on the lower surface of the lower case 9.

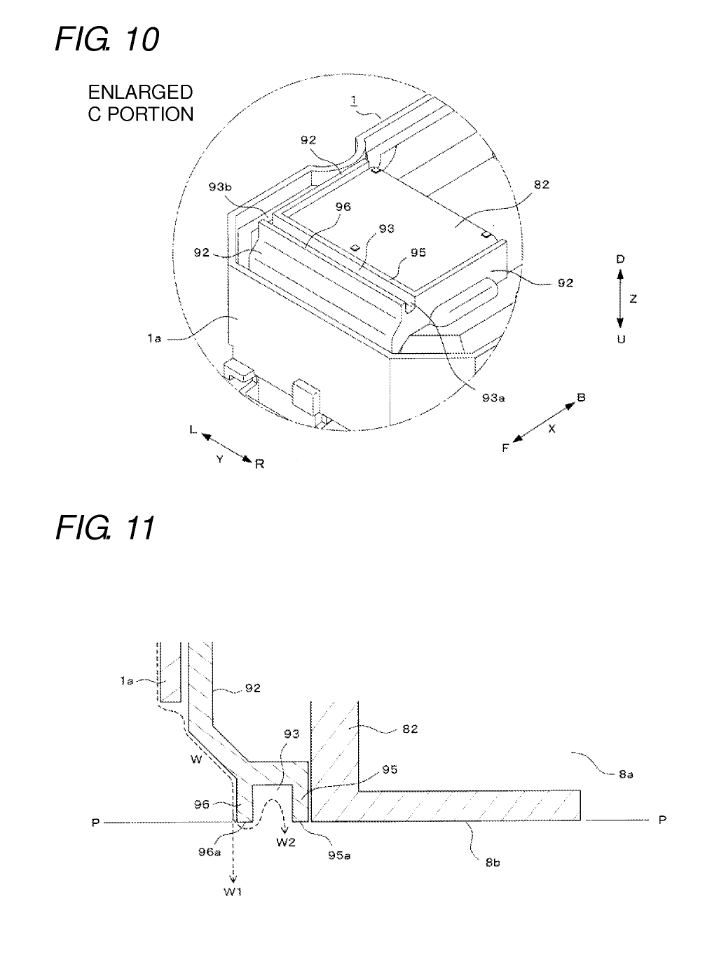

A wall portion 95 (first wall portion), a wall portion 96 (second wall portion), and a groove portion 93, which are the features of one or more embodiments of the present invention, are formed in the projection wall 92. The wall portion 95 is adjacent to a side surface 8c on the side opposite to the opening 8a of the connector box 82 as illustrated in FIG. 9, and extends in a width direction (Y-direction) of the connector box 82 as illustrated in FIG. 10. The wall portion 96 is opposed to the wall portion 95 with a space interposed therebetween as illustrated in FIG. 9, and extends in the direction (Y-direction) identical to that of the wall portion 95 as illustrated in FIG. 10. The groove portion 93 is formed between the wall portion 95 and the wall portion 96. As illustrated in FIG. 9, the groove portion 93 has a substantial U-shape in cross-section. As illustrated in FIG. 10, both ends 93a and 93b in the Y-direction of the groove portion 93 are opened.

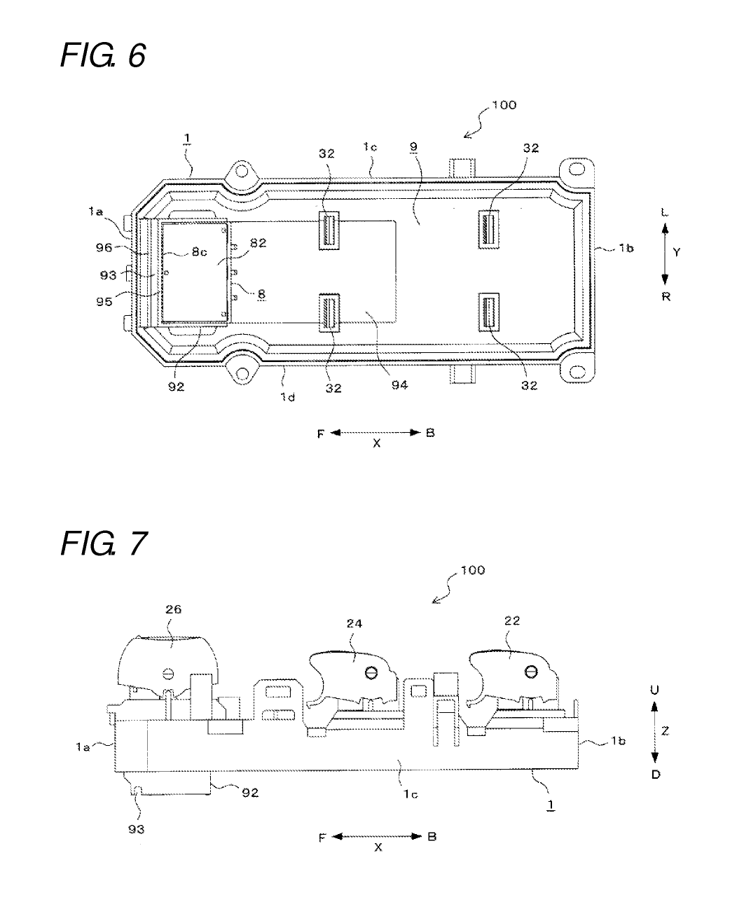

Since the connector box 82 is located at the end of the lower case 9 as illustrated in FIG. 3, the wall portion 95 and the wall portion 96 are provided near the sidewall la of the upper case 1 (see FIGS. 6, 9, and 10). As illustrated in FIG. 9, a lower surface 95a of the wall portion 95 and a lower surface 96a of the wall portion 96 constitute a surface P to be flush with a lower surface 8b of the connector box 82.

In one or more embodiments of the present invention, water W flowing down along the sidewall la of the upper case 1 drops down along part of the projection wall 92 and the wall portion 96 as indicated by a dashed line W1 in FIG. 11. However, in the case that a large amount of water W flows down, or in the case that a highly viscous liquid (hereinafter also included in the “water”) flows down, the water W flows partially toward the connector box 82 beyond the wall portion 96. The water flowing beyond the wall portion 96 flows in the groove portion 93, and drops down by its own weight as indicated by a dashed line W2. In this case, since the ends 93a and 93b (see FIG. 10) of the groove portion 93 are opened, the water flowing in the groove portion 93 also drop down from the ends 93a and 93b.

Accordingly, even if the water W flowing down along the sidewall la of the upper case 1 is about to flow along the lower surface 8b of the connector box 82, the flow of the water W is blocked by the groove portion 93 between the wall portions 95 and 96. Therefore, the water dropping down from above does not go round the opening 8a along the lower surface 8b of the connector box 82, but the water can be prevented from invading into the connector 8 or the switch device 100.

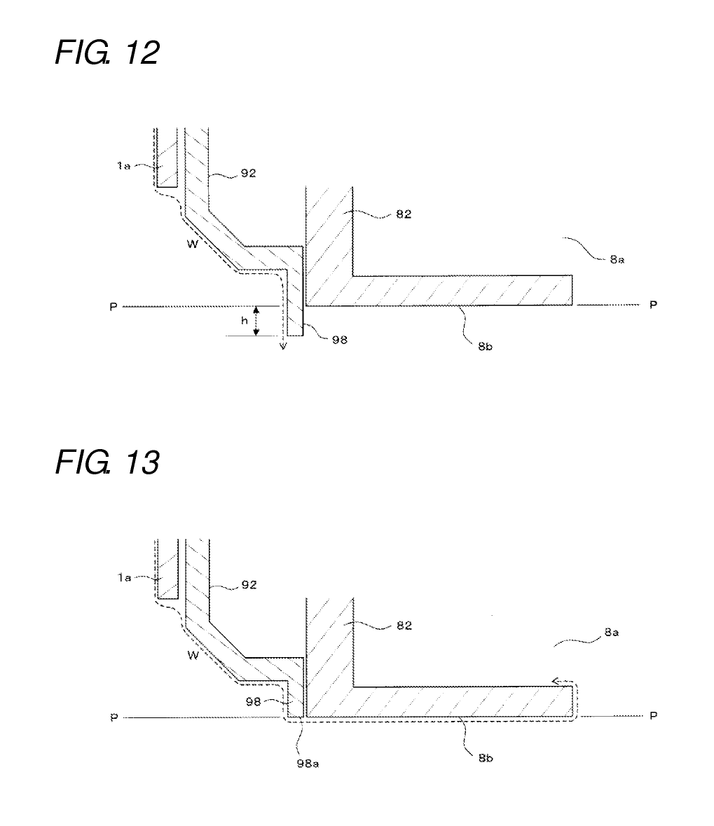

As illustrated in FIG. 12, it is also conceivable that a wall portion 98 projecting downward from the lower surface 8b of the connector box 82 is provided in order to block the water flow toward the connector box 82. However, in this case, a height of the switch device 100 increases by a projection amount h of the wall portion 98, which becomes the factor to disturb the downsizing. On the other hand, as illustrated in FIG. 13, when a lower surface 98a of the wall portion 98 is set on the surface P to be flush with the lower surface 8b of the connector box 82, although the height of the switch device 100 can be suppressed, the water W invades into the opening 8a along the lower surface 8b of the connector box 82 through a passage indicated by the dashed line.

On the other hand, in one or more embodiments of the present invention, since the water flow toward the connector box 82 can effectively be blocked by the groove portion 93 as described above, it is not necessary to increase the heights of the wall portions 95 and 96 compared with the connector box 82. That is, downsizing is achieved by suppressing the height of the switch device 100, while the invasion of the water into the switch device 100 can be prevented.

In one or more embodiments of the present invention, the drain hole 30 is formed in the upper surface of the upper case 1, and the drain hole 32 corresponding to the drain hole 30 is also formed in the lower case 9. Therefore, the water flowing down on the upper surface of the upper case 1 can be drained downward through the drain holes 30 and 32 as indicated by the dashed line W in FIG. 8. Therefore, the water can be prevented from invading into the switch device 100 through the tubes 10 from the lower sides of the operation knobs 21 to 24. The rib 10a is provided in the tube 10, so that the water going round from the lower sides of the operation knobs 21 to 24 can more effectively be blocked.

In one or more embodiments of the present invention, the V-shape groove 10b in which both the ends are opened is provided in the tube 10 (see FIG. 1), and the inverse V-shape groove 20b corresponding to the groove 10b is provided in each of the operation knobs 21 to 24 (see FIG. 8). Therefore, the water invading into the tube 10 from the back side of each of the operation knobs 21 to 24 can be received by the grooves 10b and 20b and laterally drained.

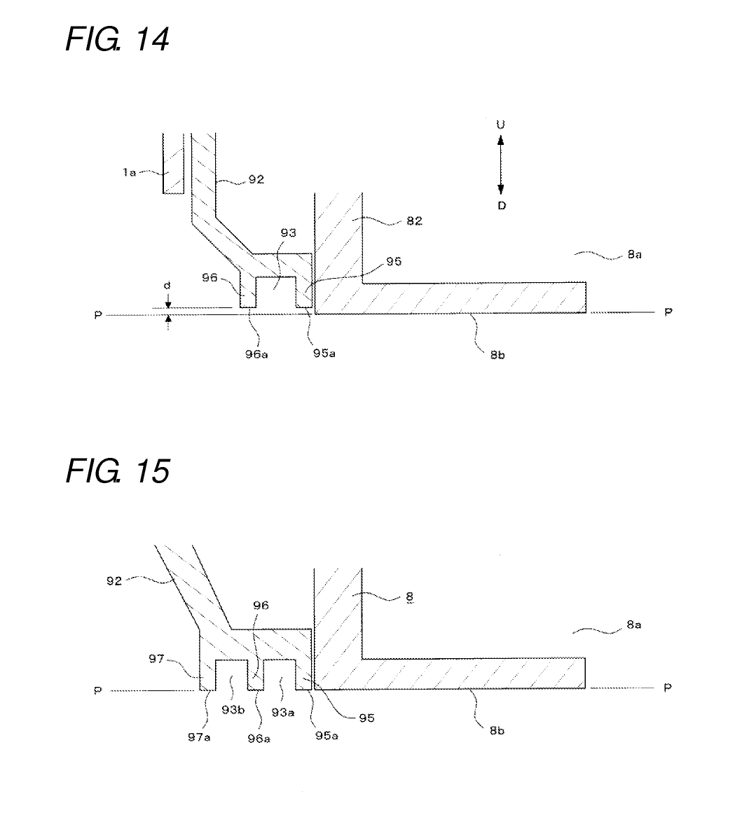

In addition to the above, various embodiments can be employed in the present invention. For example, in one or more of the above embodiments, the lower surfaces 95a and 96a of the wall portions 95 and 96 are set on the surface P to be flush with the lower surface 8b of the connector box 82 (see FIG. 9). On the other hand, as illustrated in FIG. 14, the lower surfaces 95a and 96a of the wall portions 95 and 96 may be set lower than the lower surface 8b of the connector box 82 by a predetermined amount d. That is, in one or more embodiments of the present invention, the lower surfaces 95a and 96a of the wall portions 95 and 96 are not projected downward from the lower surface 8b of the connector box 82.

As illustrated in FIG. 15, a wall portion 97 (a third wall portion) may further be provided in addition to the wall portions 95 and 96. In this case, the groove portion 93a is formed by the wall portions 95 and 96, and the groove portion 93b is formed by the wall portions 96 and 97. The lower surfaces 95a, 96a, and 97a of the wall portions 95, 96, and 97 constitute the surface P to be flush with the lower surface 8b of the connector box 82. In this case, the lower surfaces 95a, 96a, and 97a may also be set lower than the lower surface 8b by a predetermined amount. In the embodiment in FIG. 15, the water flow toward the connector box 82 can more effectively be blocked by the groove portions 93a and 93b.

In one or more embodiments of the present invention, the projection wall 92 is provided in the lower case 9, and the wall portions 95 and 96 and the groove portion 93 are formed in the projection wall 92. Alternatively, the projection wall 92 may be eliminated, and the wall portions 95 and 96 and the groove portion 93 may independently be provided.

In one or more embodiments of the present invention, the switch device 100 includes six operation knobs 21 to 26 by way of example. However, the number of operation knobs is not limited to six. The structure of the operation knob is not limited to those in the drawings. For example, one or more embodiments of the present invention can also be applied to the switch device including a rotary operation knob.

In one or more embodiments of the present invention, the vehicle automatic window switch is cited as an example of the switch device 100. Additionally, one or more embodiments of the present invention can also be applied to the switch devices used in applications except the vehicle.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A switch device comprising:
an upper case;
an operation part attached to the upper case;
a lower case fitted in the upper case;
a connector provided on a rear side of the lower case, the connector including a connector box and a connector terminal accommodated in the connector box, the connector box including an opening opened in a direction parallel to a lower surface of the lower case;
a first wall portion that extends in a width direction of the connector box while being adjacent to a side surface on a side opposite to the opening of the connector box; and
a second wall portion that extends in the same direction as the first wall portion while being opposed to the first wall portion with a gap interposed therebetween, wherein a lower surface of the first wall portion and a lower surface of the second wall portion are configured not to project downward from a lower surface of the connector box.

2. The switch device according to claim 1, wherein the lower surface of the first wall portion and the lower surface of the second wall portion are flush with the lower surface of the connector box.

3. The switch device according to claim 1,
wherein a projection wall projecting downward is provided in the lower case so as to cover the side surface except the opening of the connector box, and
wherein the first wall portion, the second wall portion, and a groove portion formed between the first wall portion and the second wall portion are provided in the projection wall.

4. The switch device according to claim 1,
wherein the connector box is located at an end of the lower case, and
wherein the first wall portion and the second wall portion are provided near a sidewall of the upper case.

5. The switch device according to claim 1, wherein both ends of the groove portion are opened in the width direction of the connector box.

6. The switch device according to claim 1, further comprising:
a circuit board that is accommodated between the upper case and the lower case,
wherein the connector terminal is connected to the circuit board.

7. The switch device according to claim 2,
wherein a projection wall projecting downward is provided in the lower case so as to cover the side surface except the opening of the connector box, and
wherein the first wall portion, the second wall portion, and a groove portion formed between the first wall portion and the second wall portion are provided in the projection wall.

8. The switch device according to claim 2,
wherein the connector box is located at an end of the lower case, and
wherein the first wall portion and the second wall portion are provided near a sidewall of the upper case.

9. The switch device according to claim 3,
wherein the connector box is located at an end of the lower case, and
wherein the first wall portion and the second wall portion are provided near a sidewall of the upper case.

10. The switch device according to claim 2, wherein both ends of the groove portion are opened in the width direction of the connector box.

11. The switch device according to claim 3, wherein both ends of the groove portion are opened in the width direction of the connector box.

12. The switch device according to claim 4, wherein both ends of the groove portion are opened in the width direction of the connector box.

13. The switch device according to claim 2, further comprising:
a circuit board that is accommodated between the upper case and the lower case,
wherein the connector terminal is connected to the circuit board.

14. The switch device according to claim 3, further comprising:
a circuit board that is accommodated between the upper case and the lower case,
wherein the connector terminal is connected to the circuit board.

15. The switch device according to claim 4, further comprising:
a circuit board that is accommodated between the upper case and the lower case,
wherein the connector terminal is connected to the circuit board.

16. The switch device according to claim 5, further comprising:
a circuit board that is accommodated between the upper case and the lower case,
wherein the connector terminal is connected to the circuit board.
